(19) United States
(12) Patent Application Publication
(10) Pub. No.: US 2011/0014354 A1
(43) Pub. Date: Jan. 20, 2011

(54) ADHESIVE COMPOSITIONS AND METHODS FOR USE IN FAILURE ANALYSIS

(76) Inventors: David Christopher Graham, Lexington, KY (US); Gary Anthony Holt, JR., Lexington, KY (US); Joel Paul Provence, Delaware, OH (US); Sean Terrence Weaver, Union, KY (US); Richard Donovan Wells, Westerville, OH (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 12/505,577

(22) Filed: Jul. 20, 2009

(51) Int. Cl. C23C 16/52; C09J 163/00; C09J 183/00; C09J 175/04; C09J 11/00

(52) U.S. Cl. 427/8; 523/400; 524/588; 524/589; 524/543

(57) ABSTRACT

Thermally curable adhesive compositions and method for failure analysis in micro-fluid ejections heads. The adhesive composition may be provided by a composition including from about 50.0 to about 95.0 percent by weight of at least one cross-linkable resin, from about 0.1 to about 30.0 percent by weight of at least one thermal curative agent, and from about 0.0 to about 5.0 percent by weight filler, from about 0.1 to about 10.0 percent by weight fluorescent pigment. Upon curing, the adhesive composition exhibits a relatively low shear modulus.

### CROSS REFERENCES TO RELATED APPLICATIONS

None.

### BACKGROUND

1. Field of the Invention

The present invention relates generally to adhesive compositions and, more particularly, to flexible compounds that can be cured for use as adhesives in micro-fluid ejection devices and used to improve failure analysis.

2. Description of the Related Art

Micro-fluid ejection heads are useful for ejecting a variety of fluids including inks, cooling fluids, pharmaceuticals, lubricants and the like. A widely used micro-fluid ejection head is an inkjet print head used in an ink printer. Ink jet printers continue to be improved as the technology for making their micro-fluid ejection heads continues to advance.

In the production of conventional thermal ink jet print cartridges for use in ink jet printers, one or more micro-fluid ejection heads are typically bonded to one or more chip pockets of an ejection device structure. A micro-fluid ejection head typically includes a fluid-receiving opening and fluid supply channels through which fluid travels a plurality of bubble chambers. Each bubble chamber includes an actuator such as a resistor which, when addressed with an energy pulse, momentarily vaporizes the fluid and forms a bubble which expels a fluid droplet. The micro-fluid ejection head typically comprises an ejector chip and a nozzle plate having a plurality of discharge orifices formed therein.

A container, which may be internal with, detachable from or remotely connected to (such as by tubing) the ejection device structure, serves as a reservoir for the fluid and includes a fluid supply opening that communicates with a fluid-receiving opening of a micro-fluid ejection head for supplying ink to the bubble chambers in the micro-fluid ejection head.

During assembly of the micro-fluid ejection head to the ejection device structure, an adhesive is used to bond the ejection head to the ejection device structure. The adhesive “fixes” the micro-fluid ejection head to the ejection device structure such that its location relative to the ejection device structure is substantially immovable and does not shift during processing or use of the ejection head. The bonding and fixing step is often referred to as a “die attach step.” Further, the adhesive may provide additional functions such as serving as a fluid gasket against leakage of fluid and as corrosion protection for conductive tracing. The latter function for the adhesive is referred to as apart of the adhesive's encapsulating function, thereby further defining the adhesive as an “encapsulant” to protect the electrical component connections, such as flexible circuit (e.g., a TAB circuit) attached to the micro-fluid ejection head, from corrosion.

However, the micro-fluid ejection head and the ejection device structure typically have dissimilar coefficients of thermal expansion. For example, the micro-fluid ejection head may have silicon or ceramic substrates that are bonded to an ejection device structure that may be a polymeric material such as modified phenylene oxide. Thus, the die attach adhesive material must accommodate both dissimilar expansions and contractions of the micro-fluid ejection head and the ejection device structure.

In the prior art, conventional adhesive and encapsulant materials tended to be non-flexible and brittle after curing due to high temperatures required for curing and the relatively high shear modulus exhibited by the adhesive materials upon curing. Such properties may cause the die attach materials to chip or crack. It may also cause the components (e.g., micro-fluid ejection head and/or ejection device structure) to bow, chip, crack, or otherwise separate from one another, or to be less resilient to external forces (e.g. chips may be more prone to crack when dropped.) For example, during a conventional thermal curing process, the ejection device structure typically expands before a conventional die attach adhesive and encapsulant material are fully cured. The die attach material thus moves with the expanding device structure, wherein the diebond material and the encapsulant material cure with the device structure in an expanded state. Upon cooling the device structure, the device structure contracts and, with a rigid cured diebond material, high stress may be induced onto the ejection head structure to cause the aforementioned bowing, chipping, cracking, separating, etc.

Such adverse effects as bowing, chipping, cracking, separating, etc., may be even more pronounced as the substrates for the device structure are made thinner. Among other problems, such events may result in fluid leaking, corrosion of electrical components, and poor adhesion as was as malfunctioning of the micro-fluid ejection heads, such as misdirected nozzles.

Moreover, in the same general area of the printhead, there are several different epoxy materials that are dispensed and/or placed in the printhead manufacturing process. It is difficult to determine visually and analytically the differences between the different epoxy materials. Clogged printhead nozzles could result if any of the epoxy materials are dispensed or processed incorrectly. Thus there is a need during manufacturing to easily identify which material is clogging the printhead in order to allow an adjustment in their processes immediately instead of subjecting the printhead to analytical analysis which requires a significant amount of time to perform.

Furthermore, as mentioned previously, the die attach material can wick up the via wall and into the printhead nozzles. This results in a blockage that does not allow ink to flow out of the printhead nozzles. Prior art die attach adhesive materials exhibit a drop in viscosity while being heated up or cured. This drop in viscosity during thermal cure leads to the undesirable wicking of the adhesive materials up the via wall. It can take significant time for an analytical analysis to determine whether or not the ink flow issue is caused by a die attach wicking issue which would result in reformulation of the die attach material. Therefore, it is necessary for the failure analysis of the die attach material to be determined during the manufacturing process quickly and without time consuming analytical analysis.

Thus, there is still a need for a new die attach adhesive composition that will provide better dimensional control, failure analysis capability, and adhesion to silicon dies to reduce reliability issues (e.g. cross contamination due to adhesion loss), improve print quality by preventing nozzle misdirection, and reduce manufacturing scrap (e.g. missing nozzles).

### SUMMARY OF THE INVENTION

The present invention meets this need by providing a die attach adhesive formulation that not only has better flow resistance and adhesion by the addition of an amine curative, but allows for the easier identification of the adhesive without use of expensive analytical methods by the addition of a fluorescent dye. The addition of fluorescent dye enables identification of the adhesive in ink flow paths from material flow during the cure process and other process dispense issues.

In one aspect, the present invention provides a thermally curable adhesive composition for attaching a micro-fluid ejection head to a device. The adhesive composition may be provided by a composition including from about 50.0 to about 95.0 percent by weight of at least one cross-linkable resin, from about 0.1 to about 30.0 percent by weight of at least one thermal curative agent, and from about 0.0 to about 50.0 percent by weight filler, fom about 0.1 to about 10.0 percent by weight fluorescent pigment, from about 0.1 to about 10.0 percent by weight of other inorganic pigments. Upon curing, the adhesive composition exhibits a relatively low shear modulus.

In another aspect of the present invention, a method is provided for failure analysis of a thermally curable adhesive composition for attaching a micro-fluid ejection head to a device. The method includes utilizing a black light (310 nm to 450 nm wavelengths) that selectively fluoresces the adhesive, thus allowing identification of the adhesive. The adhesive composition contains from about 50.0 to about 95.0 percent by weight of at least one cross-linkable resin, from about 0.1 to about 30.0 percent by weight of at least one thermal curative agent, and from about 0.0 to about 50.0 percent by weight filler, from about 0.1 to about 10.0 percent by weight fluorescent pigment, from about 0.1 to about 10.0 percent by weight of other inorganic pigments. Upon curing, the adhesive composition exhibits a relatively low shear modulus. For the purposes of certain embodiments in this disclosure, “relatively low shear modulus” is defined as shear modulus at least lower than about 10 MPa at 25° C. “Relatively low shear modulus” may, however, be defined as a shear modulus lower than about 5.0 MPa at 25° C. for certain exemplary embodiment disclosed herein.

### BRIEF DESCRIPTION OF THE DRAWINGS

Further features and advantages of the disclosed embodiments may become apparent by reference to the detailed description when considered in conjunction with the figures, which are not to scale, wherein like reference numbers indicate like elements through the several view, and wherein:

FIG. 1 is a perspective view of a micro-fluid ejection device according to an exemplary embodiment of the present invention.

FIG. 2 is a perspective view, not to scale, of an ink jet printer capable of controlling a micro-fluid ejection device according to the present invention.

FIG. 3 is a cross-sectional view, not to scale, of a portion of a micro-fluid ejection device according to the present invention.

FIG. 4A is a cross-sectional view, not to scale, of a micro-fluid ejection device incorporating one or more prior art adhesive compositions.

FIG. 4B is a cross-sectional cutaway side view, not to scale, of a portion of a micro-fluid ejection device according to the embodiment of the present invention.

### DETAILED DESCRIPTION

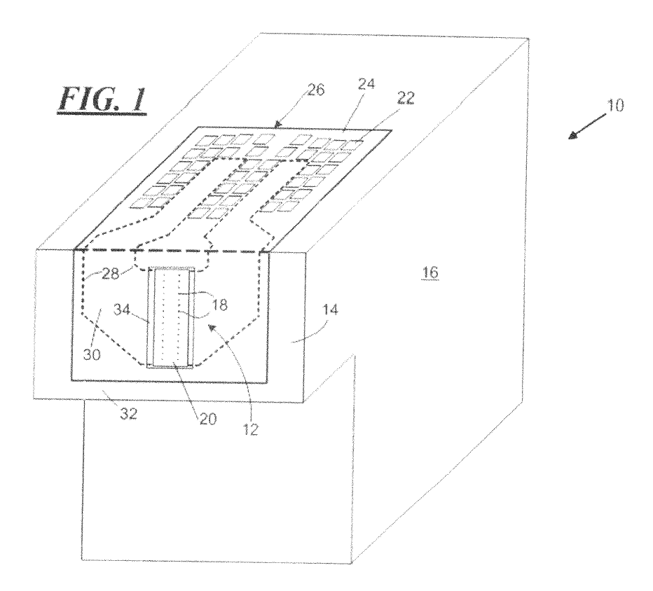

In order to more fully disclose the various embodiments of the invention, attention is directed to the following description of a representative micro-fluid ejection device incorporating the improved thermally curable adhesive described herein. With reference to FIG. 1, there is shown, in perspective view, a micro-fluid ejection device 10 including one or more micro-fluid ejection heads 12 attached to a head portion 14 of the device 10. A fluid reservoir 16 containing one or more fluids is fixedly (or removably) attached to the head portion 14 for feeding fluid to the one or more micro-fluid ejection heads 12 for ejection of fluid toward a media or substrate from nozzles 18 on a nozzle plate 20. Although FIG. 1 illustrates the fluid reservoir being directly attached to a head portion 14, other embodiments might attach a fluid reservoir indirectly to a head portion, such as by tubing, for example. Each reservoir 16 may contain a single fluid, such as black, cyan, magenta or yellow ink or may contain multiple fluids. In the illustration shown in FIG. 1, the device 10 has a single micro-fluid ejection head 12 for ejecting a single fluid. However, the device 10, may contain two or more ejection heads for ejecting two or more fluids, or a single ejection head 12 may eject multiple fluids, or other variations on the same.

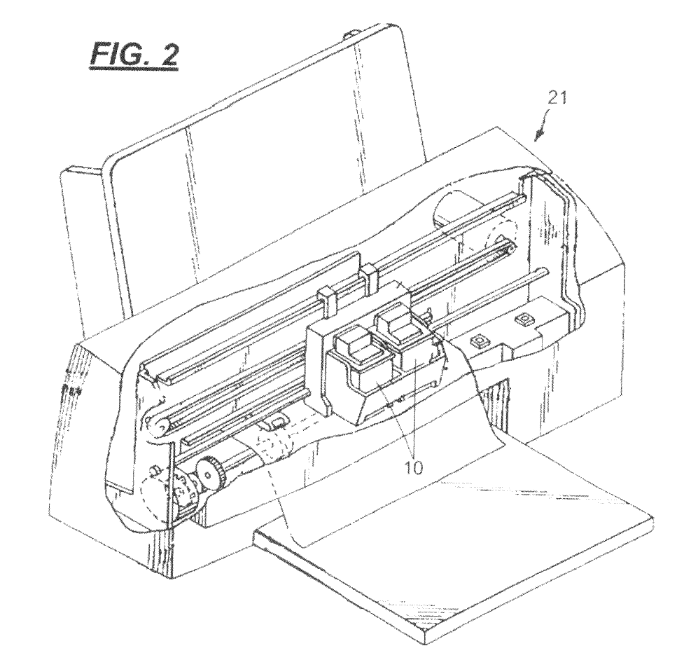

In order to control the fluid from the nozzles 18, each of the micro-fluid ejection heads 12 is usually electrically connected to a controller in an ejection control device, such as, for example, a printer 21 (FIG. 2), to which the device 10 is attached. In the illustrated embodiment, connections between the controller and the device 10 are provided by contact pads 22 which are disposed on a first portion 24 of a flexible circuit 26. An exemplary flexible circuit 26 is formed from a resilient polymeric film, such as a polyimide film, which has conductive traces 28 thereon for conducting electrical signals from a source to the ejection head 12 connected to the traces 28 of the flexible circuit 26. A second portion 30 of the flexible circuit 26 is typically disposed on an operative side 32 of the head portion 14. The reverse side of the flexible circuit 26 typically contains the traces 28 which provide electrical continuity between the contact pads 22 and the micro-fluid ejection heads 12 for controlling the ejection of fluid from the micro-fluid ejection heads 12. TAB bond or wire bond connections, for example, are made between the traces 28 and each individual micro-fluid ejection head 12 as described in more detain below.

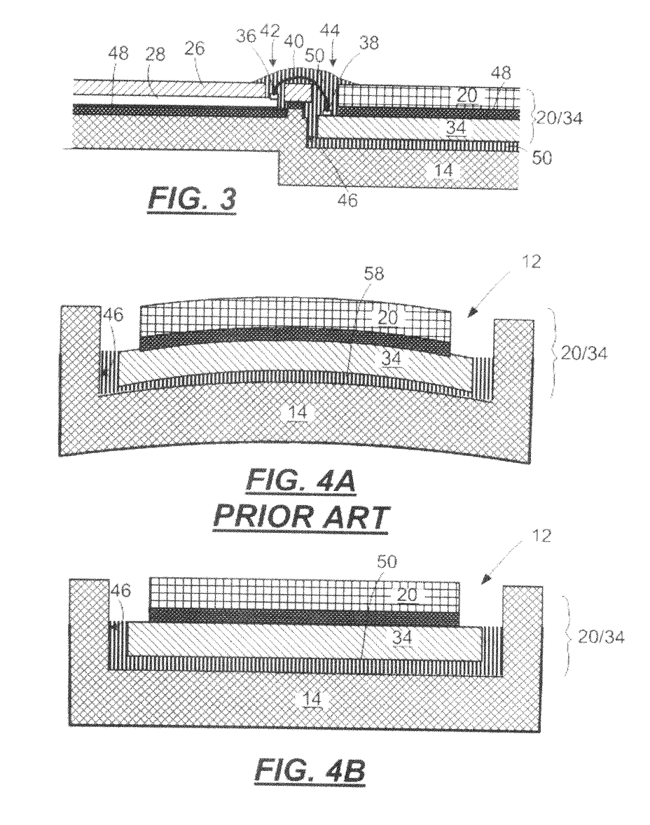

Exemplary connections between a flexible circuit and a micro-fluid ejection head are shown in detail by reference to FIG. 3. As described above, the flexible circuits 26 contain traces 28 which are electrically connected to a substrate 34. The substrate 34 may be part of an ejector chip having resistors and/or other actuators, such as piezeoelectric devices or MEMs devices for inducing ejection of fluid through nozzles 18 of nozzle plate 20 toward print media. Connection pads 36 on the flexible circuits 26 are operatively connected to bond pads 36 on the substrate 34, such as by TAB bonding techniques or by use of wires 40 using a wire bonding procedure through windows 42 and/or 44 in the flexible circuit 26 and/or nozzle plate 20.

As shown in FIG. 3, the substrate 34 is attached to the head portion 14, such as in a chip pocket 46. Prior to attaching the substrate 34 to the head portion 14, a nozzle plate 20 may be adhesively attached to the ejector chip using adhesive 48 (in another embodiment, a nozzle plate may be attached to the ejector chip by forming the nozzle plate on the substrate using photoimageable techniques). The assembly provided by the nozzle plate 20 attached the substrate 34 is referred to herein as the substrate/nozzle plate assembly 20/34 (FIG. 3). In some embodiments, the assembly 20/34 encompasses the micro-fluid ejection head itself.

The adhesive 48 may be a heat curable adhesive such as B-stageable thermal cure resins including, but not limited to, phenolic resins, resorcinol resins, epoxy resins, ethylene-urea resins, furane resins, polyurethane resins and silicone resins. The adhesive 48 may be cured before attaching the substrate 34 to the head portion 14 and, in an exemplary embodiment, the adhesive 48 has a thickness ranging from about 1 to about 25 microns.

After bonding the nozzle plate 20 and substrate 34 together, the substrate/nozzle plate assembly 20/34 may be attached to the head portion 14 in chip pocket 46 using a die bond adhesive 50. In various embodiments of the present invention, the die bond adhesive 50 used to connect the substrate nozzle plate assembly 20/34 to the head portion 14 includes one or more adhesive components that make up a composition having a relatively low shear modulus.

“Shear modulus” involves the relation of stress to strain according to Hooke's Law as shown in Equation (1) as follows:

(stress)=μ(strain) (1)

In Equation (1) μ represents a quantity often referred to as rigidity. When the relationship illustrated by Equation (1) is applied to a force “F” across a given area “A,” Equation (1) may be more specifically represented by Equation (2) as follows:

F/A=μ(ΔL/L) (2)

In Equation (2) above, the variable “L” represents original length of an object before said object was acted upon by force F. “ΔL” represents the change in length occurring after force “F” has acted upon the object. Therefore, the rigidity (“μ”) of the object is a proportionality constant relating the pressure applied to an object with the ratio between the object change in length with the objects original length.

When Equation (2) and a given rigidity value “μ” are used to determine elastic properties of an object, Equation (3), shown below, is used to derive a shear modulus value from the rigidity μ value determined in Equation (2). Equation (3) is shown below as follows:

μ=E/2(L+v) (3)

In Equation (3) above, shear modulus is the proportional relationship between rigidity “μ” and the right hand side of the equation, including the Poisson ratio “v” and Young's modulus “E.”

Applying Hooke's Law and elasticity theory to physical properties of micro-fluid ejection heads, reliable data may be established to correlate the elastic properties of adhesives with the effect of said adhesives on one or more surfaces of a micro-fluid ejection head, Shear modulus values are dependent on temperature, therefore, a given shear modulus value for a given adhesive will be given in pressure units at a specific temperature. Various embodiments of the disclosure include compositions with shear modulus values of less than 10 MPa at 25° C. as determine by a rheometer from TA Instruments of New Castle, Del. under the trade name ARES in a dynamic parallel plate configuration with a frequency of 1.0 rad/sec and a strain of 0.3% after the material is cured.

With reference now to FIG. 4A, a cross-sectional view of a non-planar micro-fluid ejection head 12 (e.g., substrate/nozzle plate assembly 20/34) is illustrated. The substrate/nozzle plate assembly 20/34 is attached to a head portion 14 in a chip pocket 46. In the prior art ejection head 12, the substrate/nozzle plate assembly 20/34 was attached to the chip pocket 46 using a prior art die attach adhesive 58 having a shear modulus of substantially more than 10 MPa at 25° C. The non-planar characteristic of micro-fluid ejection head 12 is caused at least in part by high temperature curing of the die attach adhesive 58.

The example shown in FIG. 4A is provided to illustrate certain undesirable effects of high temperature curing including non-planar micro-fluid ejection head surfaces causing undesirable effects such as “chip bowing,” adhesive layer cracking, and increased overall fragility of the micro-fluid ejection head 12 and substrate/nozzle plate assembly 20/34. Chip bowing typically results from the substrate/nozzle plate assembly 20/34 and the head portion 14 having dissimilar coefficients of thermal expansion, since the surface of the substrate/nozzle plate assembly 20/34 bonded to the head portion 14 most commonly is silicon or ceramic and the portion 14 is, for example, typically a polymeric material such as a modified phenylene oxide, Thus, the adhesive 58 should be flexible enough to accommodate both the dissimilar expansions and contractions of the substrate chip/nozzle plate assembly 20/34 and the head portion 14. Chip bowing may result in nozzles being misaligned or aligned at an undesired angle (often called “planarity” of nozzles), which may also diminish the quality of fluid ejected from the nozzles.

Chip fragility is believed to increase in severity because the adhesive layer reaches its glass transition temperature (T_{g}) before the substrate/nozzle plate assembly 20/34 and head portion 14 have finished cooling and contracting relative to one another after the curing of the adhesive layer 58, imparting stress onto the substrate/nozzle plate assembly. Accordingly, in an exemplary embodiment of the invention, an adhesive is used that has glass transition temperature below the temperature to which the head portion 14 is cooled. For example, an adhesive with a glass transition temperature of less than about 65° C., such as one having a glass transition temperature of less than about 50° C. or less than about 25° C. might be used in an exemplary embodiment.

The glass transition temperature of a material with elastic properties is the temperature at which the material transitions to more brittle physical properties or more elastic physical properties, depending on whether the temperature is decreasing or increasing, respectively. After curing, as the adhesive layer 58 cools below its glass transition temperature, the adhesive 58 becomes significantly more brittle than before reaching its glass transition temperature. If the adhesive 58 is stretched or compressed at a temperature below its glass transition temperature, the adhesive may crack or buckle. Therefore, using adhesives with lower glass transition temperatures will decrease the chances of adhesive cracking or buckling, Similarly, considering that shear modulus values directly relate to how brittle an adhesive will be at a given temperature, adhesives having lower shear modulus values are more flexible at lower temperatures, thereby decreasing the likelihood of adhesive cracking or buckling. Adhesive layer cracking may result in a compromised fluid seal, whereby micro-fluid ejection fluid leaks from the substrate/nozzle plate assembly 20/34 might cause undesirable deposits of fluid, and/or corrosion of electrical components.

High curing temperatures may also cause increased fragility. Adhesives having lower shear modulus values and lower glass transition temperatures may be cured with lower temperatures thereby, decreasing the chances for micro-fluid ejection head fragility. Increased fragility of micro-fluid ejection heads increases the chances for micro-fluid ejection products becoming unfit for use due to shattering of micro-fluid ejections heads and other parts of the micro-fluid ejection device.

In contrast to FIG. 4A, the head portion 14 shown in FIG. 4B illustrates a micro-fluid ejection head 12 comprising a substrate/nozzle plate assembly 20/34 that is attached to the chip pocket 46 using die attach adhesive 50 made of one or more of the compositions described herein. Using compositions such as that described below may result in decreased chip bowing, decreased micro-fluid ejection head cracking, and/or decreased fragility of micro-fluid ejection heads. Such improved characteristics may be possible by the use of a die attach adhesive having a relatively low shear modulus. For the purposes of certain embodiments in this disclosure, “relatively low shear modulus” is defined as a shear modulus at least lower than about 10 MPa at 25° C. “Relatively low shear modulus” may, however, be defined as a shear modulus lower than about 1.0 MPa at 25° C. for certain exemplary embodiments disclosed herein.

In an exemplary embodiment, the thermally curable adhesive 50 may be a composition including (1) from about 50.0 to about 95.0 percent by weight of at least one cross-linkable resin selected from the group of epoxy resins, silicone resins, urethanes resins, and functionalized olefin resins; (2) from about 0.1 to about 30.0 percent by weight of at least one thermal curative agent selected from the group of imidazoles, amines, antimonites, peroxides, organic accelerators and sulfur; (3) from about 0.0 to about 50.0 percent by weight filler; and (4) from about 0.1 to about 10.0 percent by weight fluorescent pigment, wherein the composition exhibits a relatively low shear modulus upon curing. In some variation of these exemplary embodiments, the thermally curable adhesive may include from about 0.0 to 10.0 percent by weight silane coupling agent. In some variation of these exemplary embodiments, the thermally curable adhesive may include from about 0.0 to about 50.0 percent by weight a phenolic cross linking agent from the group of bisphenol-F and bisphenol-M. In some variation of these exemplary embodiments, the cross-linkable resin of the thermally curable adhesive may be an epoxy resin with a flexible backbone. In some variation of these exemplary embodiments, the thermally curable adhesive may include from about 0.0 to about 50.0 percent by weight a low molecular weight epoxy resin from the group of diglycidyl ether of bisphenol-F and diglycidyl ether of bisphenol-A. In the embodiments described above, the filler may include from about 0.0 to about 50.0 percent by weight fumed silica or another filler component such as clay or functionalized clay, silica, talc, carbon black, carbon fibers.

An exemplary embodiment of the thermally curable adhesive composition according to the present invention is listed in Table 1.

TABLE 1
(Adhesive Composition 1)

| | Concentration | | |
|---|---|---|---|
| | (percent by | | |
| Material | weight) | Trade Name | Supplier |
| Flexible epoxy | 50.0-95.0 | EXA-4850 | Dainippon Ink |
| Resin | | | and Chemicals, |
| | | | Inc. |
| Diglycidyl ether | 15.0-45.0 | 830LVP | Dainippon Ink |
| of bisphenol-F | | | and Chemicals, |
| | | | Inc. |
| Imidazole | 10.0-12.0 | CUREZOl-17-Z | Air Products |
| Catalyst | | | |
| Epoxy Silane | 0.1-2.0 | A-187 | Crompton |
| Fumed Silica | 0.0-2.0 | TS-720 | Cabot |
| Amine adduct | 0.1-15.0 | ANCAMINE 2337 | Air Products |
| Fluorescent | 0.1-1.0 | UVITEX OB | Ciba |
| Pigment | | | |

As shown above, adhesive composition 1 includes from about 50.0 to about 95.0 percent by weight multi-functional epoxy resin. The composition also includes from about 10.0 to about 12.0 percent by weight of an imidazole catalyst and from about 0.0 to about 5.0 percent by weight filler and from about 0.1 to about 1.0 percent by weight fluorescent pigment. The composition also includes from about 0.1 to about 15.0 percent by weight amine adduct. Optional components include from about 0.1 to about 2.0 percent by weight silane coupling agent and from about 0.1 to about 10.0 percent by weight of other inorganic pigments. An exemplary multifunctional epoxy resin is available from Dainippon Ink and Chemicals, Inc. of Tokyo, Japan under the trade name EPICLON EXA-4850.

A suitable co-epoxy cross-linking agent is available from Dainippon Ink and Chemicals, Inc. of Tokyo, Japan under the trade designation 830LVP. A useful curing agent is available from Air Products and Chemicals, Inc. under the trade name CUREZOL C 17Z. A suitable expoxy silane coupling agent is available from GE Advanced Materials, Silicones of Wilton, Con. Under the trade name SILQUEST A-187 SILANE. A suitable filler, such as fumed silica, is available from a number of different suppliers. For example, fumed silica is available from Cabot Corporation of Boston, Mass. under the trade name CAB-O-SIL TS-720, A suitable amine adduct is available from Air Products and Chemical, Inc. under the trade name ANCAMINE 2337. A suitable fluorescent pigment is available from CIBA under the trade name Uvitex OB.

More specific exemplary embodiments of the composition of the adhesive 50 and the materials contained therein are listed in Table 2-Table 4 below. A listing of materials contained in a conventional die attach adhesive composition is found in Table 5.

The adhesive compositions 2-4 shown in Tables 2-4 below were evaluated for use in an inkjet print cartridge, such as inkjet print cartridge 100 of FIG. 1. More specifically, the evaluation was carried out to analyze different properties of the Adhesive Compositions 2-4 when disposed adjacent to a micro-f uid ejection heads of the inkjet print cartridge. The properties that were analyzed included Young's modulus (E), Shear Modulus (G′), Glass transition temperature (Tg) and Wicking Scale. For experimental purposes, the Shear modulus was measured using TA Instruments ARED rheometer at a temperature of about 25° C. after cure. The glass transition temperature was measured by modulated differential scanning calorimetery (MDSC). The flow of the adhesive during the die attach adhesive cure process can wick up chip via walls or other ink flow channels, blocking or impeding ink flow into the nozzles. Therefore, the adhesive compositions 2-4 and the prior art die attach adhesive composition were rated on a Wicking Scale wherein a scaled score of 1 wicks the most and a scaled score of 10 wicks the least which is a qualitative grading of the amount of wicking on a finish printhead assembly.

The properties of the adhesive compositions 2-4 found in Tables 2-4 were analyzed and compared to properties of a prior art die attach adhesive composition shown in Table 5. Results of this comparative analysis are shown in Table 6.

TABLE 2
(Adhesive Composition 2)

| | Concentration | | |
|---|---|---|---|
| | (percent by | | |
| Material | weight) | Trade Name | Supplier |
| Flexible epoxy | 62.8 | EXA-4850 | Dainippon Ink |
| Resin | | | and Chemicals, |
| | | | Inc. |
| Diglycidyl ether | 20.9 | 830LVP | Dainippon Ink |
| of bisphenol-F | | | and Chemicals, |
| | | | Inc. |
| Imidazole | 9.4 | CUREZOl-17-Z | Air Products |
| Catalyst | | | |
| Epoxy Silane | 0.8 | A-187 | Crompton |
| Fumed Silica | 1.7 | TS-720 | Cabot |
| Amine adduct | 4.2 | ANCAMINE 2337 | Air Products |
| Fluorescent | 0.1 | UVITEX OB | Ciba |
| Pigment | | | |

As shown above, composition 2 includes 62.8 percent by weight multi-functional epoxy resin and 20.9 percent by weight low molecular weight epoxy. The composition also includes 9.4 percent by weight of an imidazole catalyst and 1.7 percent by weight filler and 0.1 percent by weight fluorescent pigment. The composition also includes 4.2 percent by weight amine adduct Optional components include 0.8 percent by weight silane coupling agent and from about 0.1 to about 10.0 percent by weight of other inorganic pigments. An exemplary multifunctional epoxy resin is available from Dainippon Ink and Chemicals, Inc. of Tokyo, Japan under the trade name EPICLON EXA-4850

A suitable co-epoxy cross-linking agent is available from Dainippon Ink and Chemicals, Inc. of Tokyo, Japan under the trade designation 830LVP. A useful curing agent is available from Air Products and Chemicals, Inc. under the trade name CUREZOL C 17Z. A suitable expoxy silane coupling agent is available from GE Advanced Materials, Silicones of Wilton, Conn Under the trade name SILQUEST A-187 SILANE. A suitable filler, such as fumed silica, is available from a number of different suppliers. For example, fumed silica is available from Cabot Corporation of Boston, Mass. under the trade name CAB-O-SIL TS-720, A suitable amine adduct is available from Air Products and Chemical, Inc. under the trade name ANCAMINE 2337. A suitable fluorescent pigment is available from CIBA under the trade name Uvitex OB.

TABLE 3
(Adhesive Composition 3)

| | Concentration | | |
|---|---|---|---|
| | (percent by | | |
| Material | weight) | Trade Name | Supplier |
| Flexible epoxy | 60.3 | EXA-4850 | Dainippon Ink |
| Resin | | | and Chemicals, |
| | | | Inc. |
| Diglycidyl ether | 20.1 | 830LVP | Dainippon Ink |
| of bisphenol-F | | | and Chemicals, |
| | | | Inc. |
| Imidazole | 9.0 | CUREZOl-17-Z | Air Products |
| Catalyst | | | |
| Epoxy Silane | 0.8 | A-187 | Crompton |
| Fumed Silica | 1.6 | TS-720 | Cabot |
| Amine adduct | 8.0 | ANCAMINE 2337 | Air Products |
| Fluorescent | 0.1 | UVITEX OB | Ciba |
| Pigment | | | |

As shown above, composition 3 includes 60.3 percent by weight multi-functional epoxy resin and 20.1 percent by weight low molecular weight epoxy. The composition also includes 9.0 percent by weight of an imidazole catalyst and 1.6 percent by weight filler and 0.1 percent by weight fluorescent pigment. The composition also includes 8.0 percent by weight amine adduct. Optional components include 0.8 percent by weight silane coupling agent and from about 0.1 to about 10.0 percent by weight of other inorganic pigments. An exemplary multifunctional epoxy resin is available from Dainippon Ink and Chemicals, Inc. of Tokyo, Japan under the trade name EPICLON EXA-4850.

A suitable co-epoxy cross-linking agent is available from Dainippon ink and Chemicals, Inc. of Tokyo, Japan under the trade designation 830LVP. A useful curing agent is available from Air Products and Chemicals, Inc. under the trade name CUREZOL C17Z. A suitable expoxy silane coupling agent is available from GE Advanced Materials, Silicones of Wilton, Conn. Under the trade name SILQUEST A-187 SILANE. A suitable filler, such as fumed silica, is available from a number of different suppliers. For example, fumed silica is available from Cabot Corporation of Boston, Mass. under the trade name CAB-O-SIL TS-720. A suitable amine adduct is available from Air Products and Chemical, Inc. under the trade name ANCAMINE 2337. A suitable fluorescent pigment is available from CIBA under the trade name Uvitex OB.

TABLE 4
(Adhesive Composition 4)

| | Concentration | | |
|---|---|---|---|
| | (percent by | | |
| Material | weight) | Trade Name | Supplier |
| Flexible epoxy | 58.0 | EXA-4850 | Dainippon Ink |
| Resin | | | and Chemicals, |
| | | | Inc. |
| Diglycidyl ether | 19.3 | 830LVP | Dainippon Ink |
| of bisphenol-F | | | and Chemicals, |
| | | | Inc. |
| Imidazole | 8.7 | CUREZOl-17-Z | Air Products |
| Catalyst | | | |
| Epoxy Silane | 0.8 | A-187 | Crompton |
| Fumed Silica | 1.5 | TS-720 | Cabot |
| Amine adduct | 11.6 | ANCAMINE 2337 | Air Products |
| Fluorescent | 0.1 | UVITEX OB | Ciba |
| Pigment | | | |

As shown above, composition 4 includes 58.0 percent by weight multi-functional epoxy resin and 19.3 percent by weight low molecular weight epoxy. The composition also includes 8.7 percent by weight of an imidazole catalyst and 1.5 percent by weight filler and 0.1 percent by weight fluorescent pigment. The composition also includes 11.6 percent by weight amine adduct Optional components include 0.8 percent by weight silane coupling agent and from about 0.1 to about 10.0 percent by weight of other inorganic pigments. An exemplary multifunctional epoxy resin is available from Dainippon Ink and Chemicals, Inc. of Tokyo, Japan under the trade name EPICLON EXA-4850.

A suitable co-epoxy cross-linking agent is available from Dainippon Ink and Chemicals Inc. of Tokyo, Japan under the trade designation 830LVP. A useful curing agent is available from Air Products and Chemicals, Inc. under the trade name CUREZOL C17Z. A suitable expoxy silane coupling agent is available from GE Advanced Materials, Silicones of Wilton, Con. Under the trade name SILQUEST A-187 SILANE. A suitable filler, such as fumed silica, is available from a number of different suppliers. For example, fumed silica is available from Cabot Corporation of Boston, Mass. under the trade name CAB-O-SIL TS-720. A suitable amine adduct is available from Air Products and Chemical, Inc. under the trade name ANCAMINE 2337. A suitable fluorescent pigment is available from CIBA under the trade name Uvitex OB.

TABLE 5
(Prior Art Die Attach Adhesive Composition)

| | Concentration | | |
|---|---|---|---|
| | (percent by | | |
| Material | weight) | Trade Name | Supplier |
| Flexible epoxy | 65.6 | EXA-4850 | Dainippon Ink |
| Resin | | | and Chemicals, |
| | | | Inc. |
| Diglycidyl ether | 21.9 | 830LVP | Dainippon Ink |
| of bisphenol-F | | | and Chemicals, |
| | | | Inc. |
| Imidazole | 9.8 | CUREZOl-17-Z | Air Products |
| Catalyst | | | |
| Epoxy Silane | 0.9 | A-187 | Crompton |
| Fumed Silica | 1.7 | TS-720 | Cabot |
| Amine adduct | 0 | ANCAMINE 2337 | Air Products |
| Fluorescent | 0.1 | UVITEX OB | Ciba |
| Pigment | | | |

As shown above, the prior art die attach adhesive composition includes 65.6 percent by weight multi-functional epoxy resin and 21.9 percent by weight low molecular weight epoxy. The composition also includes 9.8 percent by weight of an imidazole catalyst and 1.7 percent by weight filler and 0.1 percent by weight fluorescent pigment. Optional components include 0.8 percent by weight silane coupling agent and from about 0.1 to about 10.0 percent by weight of other inorganic pigments. An exemplary multifunctional epoxy resin is available from Dainippon Ink and Chemicals, Inc, of Tokyo, Japan under the trade name EPICLON EXA-4850.

A suitable co-epoxy cross-linking agent is available from Dainippon Ink and Chemicals, inc. of Tokyo, Japan under the trade designation 830LVP. A useful curing agent is available from Air Products and Chemicals, Inc. under the trade name CUREZOL C17Z. A suitable expoxy silane coupling agent is available from GE Advanced Materials, Silicones of Wilton, Conn. Under the trade name SILQUEST A-187 SILANE. A suitable filler, such as fumed silica, is available from a number of different suppliers. For example, fumed silica is available from Cabot Corporation of Boston, Mass. under the trade name CAB-O-SIL TS-720. A suitable fluorescent pigment is available from CIBA under the trade name Uvitex OB.

TABLE 6

| | Amine | Young's | Shear | | Wicking Scale |
|---|---|---|---|---|---|
| | Concentration | Modulus (E) | Modulus | Glass transition | 1 wicks the |
| | (parts by | at 25° C. | (G′) at 25° C. | temperature | most, 10 wicks |
| | weight) | (MPa) | (MPa) | (Tg) (° C.) | the least |
| Conventional | 0 | 57 | .259 | 5.4 | 1 |
| Attach | | | | | |
| Adhesive | | | | | |
| Composition | | | | | |
| Adhesive | 5 | 07 | .470 | 46.5 | 6 |
| Composition 2 | | | | | |
| Adhesive | 0 | 64 | .13 | 55.3 | 8 |
| Composition 3 | | | | | |
| Adhesive | 15 | 045 | .890 | 76.1 | 10 |
| Composition 4 | | | | | |

It should be apparent to a person skilled in the art that, the term “Young's modulus” used herein may be defined as the ratio of tensile stress to tensile strain as shown in Equation (4) below:

Young's modulus (E)=Tensile stress/Tensile strain (4)

As used herein, the tensile stress is defined in terms of a force “F” that may be applied across an area “A” of a solid object, and tensile strain is defined in terms of change in length (ΔL) of the object of length “L” where the force is applied.

Further, the term “Shear Modulus” is used in dynamic mechanical testing of viscoelastic materials, and is defined according to below mentioned Equation (5) where τ′ is the in-phase shear stress and γ′ is the in-phase shear strain.

Shear modulus (G′)=τ′/γ′ (5)

As used herein, the shear stress is defined in terms of force “F” applied across the area “A” of the solid object, and shear strain is defined in terms of a change in transversal length (Δx) of the object of transversal length “H”.

Furthermore, the term “Glass transition temperature” of a material with elastic properties is the temperature at which the material undergoes transitions to more brittle physical properties or more elastic physical properties, depending on whether the temperature is decreasing or increasing, respectively.

Referring again to Table 6, it may be seen that the adhesive compositions 2-4 exhibit a Young's modulus from about 700 to about 1100 Mega Pascal (MPa), and a Shear modulus from about 8.4 to about 9.2 MPa at a temperature of about 25° C.

For providing adequate protection to the micro-fluid ejection heads, it is desired that the adhesive compositions 2-4 exhibit low deformation when subjected to shearing forces. In light of the aforementioned values of Young's modulus, it should be understood that adhesive compositions 2-4 exhibit relatively low deformation under shearing forces in comparison to the prior art die attach adhesive composition. The aforementioned advantage to adhesive compositions 2-4 is providing adequate protection to the micro-fluid ejection heads, thereby increasing shelf life of the inkjet cartridge.

Additionally, for providing adequate protection to the micro-fluid ejection heads, it is desirable that the adhesive compositions 2-4 exhibit high reversible deformation behavior when subjected to shearing forces. In light of the aforementioned values of Shear modulus, it should be understood that adhesive compositions 2-4 exhibit a relatively high reversible deformation behavior under shearing forces in comparison to the prior art die attach adhesive composition.

Additionally, it may be seen that adhesive compositions 2-4 exhibit a glass transition temperature from about 45° C. to about 77° C. As seen in Table 6, adhesive compositions 2-4 exhibit a higher glass transition temperature in comparison to the prior art die attach adhesive composition. Therefore, adhesive compositions 2-4 after performing curing thereof, exhibit good rigidity upon cooling.

Moreover, the adhesive compositions 2-4 exhibit relatively low wicking, More specifically, the adhesive compositions 2-4 exhibited from about 6 to about 10 on the wicking scale. As seen in Table 6, adhesive compositions 2-4 exhibit lower wicking in comparison to the prior art die attach adhesive composition. The addition of fluorescent dye enables identification of the adhesive in ink flow paths from material flow during the cure process and other process dispense issues.

Although adhesive composition 4 is the preferred embodiment, one skilled in the art of designing micro-fluid ejection systems will understand that the degree of wicking in a system is driven by the wettablity of the surfaces that the ejected fluid will be in contact with. The ejected fluid must be able to fill all of the fluid paths in the ejection system without causing fluid starvation during use. If the fluid being ejected allows the use of a less wettable surface, then the adhesive dese bed in composition 2, would allow the designer to achieve a low stress system with little-to-no wicking. While systems that require very wettable surfaces would require adhesive composition 4 with the trade-off of higher modulus system being utilize.

Accordingly, the present invention provides an effective thermally curable adhesive for protecting a micro-fluid ejection heads of an inkjet print cartridge. The adhesive composition of the present invention provides a good adhesion to surfaces of the micro-fluid ejection heads, such as a silicon chip and ejection device structures that may be a polymeric material such as modified phenylene oxide. Further, the adhesive composition allows for the easier identification of the adhesive in the printhead without use of expensive analytical methods by the addition of a fluorescent dye. The addition of fluorescent dye enables identification of the adhesive in ink flow paths from naterial flow during the cure process and other process dispense issues. Furthermore, the adhesive composition provides better dimensional control, failure analysis capability, and adhesion to silicon dies to reduce reliability issues (e.g. cross contamination due to adhesion loss), and improves print quality by preventing nozzle misdirection, and reduces man ufacturing scrap (e.g. missing nozzles).

The foregoing description of several embodiments of the invention has been presented for purposes of illustration. It is not intended to be exhaustive or to limit the invention to the precise forms disclosed, and obviously many modifications and variations are possible in light of the above teaching. It is intended that the scope of the invention be defined by the claims appended hereto.

What it claimed is:

1. A thermally curable adhesive composition for attaching a micro-fluid ejection head to a device, the adhesive comprising:
a. from about 50.0 to about 95.0 percent by weight of at least one cross-linkable resin selected from the group consisting of epoxy resins, silicone resins, urethane resins, and functionalized olefin resins;
b. from about 0.1 to about 30.0 percent by weight of at least one thermal curative agent;
c. from about 0.0 to about 50.0 percent by weight filler;
d. from about 0.1 to about 10.0 percent by weight fluorescent pigment
wherein the composition exhibits a relatively low shear modulus upon curing.

2. The adhesive composition of claim 1 wherein at least one thermal curative agent comprises a curative agent selected from the group consisting of imidazoles, amines, antimonites, peroxides, organic accelerators and sulfur.

3. The adhesive composition of claim 1 further comprising form about 0.0 to about 10.0 percent by weight silane coupling agent.

4. The adhesive composition of claim 1 wherein the filler comprises from about 0.0 to about 50.0 percent by weight fumed silica.

5. The adhesive composition of claim 1 further comprising from about 0.0 to about 50.0 percent by weight a phenolic cross-linking agent.

6. The adhesive composition of claim 5 wherein the phenolic cross-linking agent is selected from the group consisting of bisphenol-F and bisphenol-M.

7. The adhesive composition of claim 1 wherein at least one thermal curative agent comprises an imidazole catalyst.

8. The adhesive composition of claim 1 wherein at least one thermal curative agent comprises an epoxy adduct of an aliphatic poly mine containing a primary amino group.

9. The adhesive composition of claim 1 wherein the cross-linkable resin comprises of an epoxy resin with a flexible backbone.

10. The adhesive composition of claim 9 wherein the flexible backbone of the epoxy resin is selected from the group consisting of polyglycol, polybutadiene and polysilsoxane structures.

11. A method for failure analysis of a thermally curable adhesive composition for attaching a micro-fluid ejection to a device comprising
a. applying a thermally adhesive composition for attaching a micro-fluid ejection to a device adjacent to a fluid ejection surface of the ejection head, the adhesive comprising
i. from about 50.0 to about 95.0 percent by weight of at least one cross-linkable resin selected from the group consisting of epoxy resins
silicone resins, urethane, resins, and functionalized olefin resins;
ii. from about 0.1 to about 30.0 percent by weight of at least one thermal curative agent
iii. from about 0.0 to about 50.0 percent by weight filler;
iv. from about 0.1 to about 10.0 percent by weight fluorescent pigment
wherein the composition exhibits a relatively low shear modulus upon curing.
b. placing the micro-fluid election head using said composition under a black light to selectively fluoresce the adhesive allowing identification of the adhesive; and
c. identifying adhesive in ink flow paths from material flow during the cure process.

12. The adhesive composition of claim 11 wherein at least one thermal curative agent comprises a curative agent selected from the group consisting of imidazoles, amines, antimonites, peroxides organic accelerators and sulfur.

13. The adhesive composition of claim 11 further comprising form about 0.0 to about 10.0 percent by weight silane coupling agent.

14. The adhesive composition of claim 11 wherein the filler comprises from about 0.0 to about 50.0 percent by weight fumed silica.

15. The adhesive composition of claim 11 further comprising from about 0.0 to about 50.0 percent by weight a phenolic cross-linking agent.

16. The adhesive composition of claim 15 wherein the phenolic cross-linking agent is selected from the group consisting of bisphenol-F and bisphenol-M.

17. The adhesive composition of claim 11 wherein at least one thermal curative agent comprises an imidazole catalyst.

18. The adhesive composition of claim 11 wherein at least one thermal curative agent comprises an epoxy adduct of an aliphatic poly amine containing a primary amino group.

19. The adhesive composition of claim 11 wherein the cross-linkable resin comprises of an epoxy resin with a flexible backbone.

20. The adhesive composition of claim 9 wherein the flexible backbone of the epoxy resin is selected from the group consisting of polyglycol, polybutadiene and polysilsoxane structures.
